(19) United States
(12) Patent Application Publication
(10) Pub. No.: US 2009/0126623 A1
(43) Pub. Date: May 21, 2009

(54) Apparatus for producing group III element nitride semiconductor and method for producing the semiconductor

(75) Inventor: Shiro Yamazaki, Aichi-ken (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: TOYODA GOSEI CO., LTD., Aichi-ken (JP)

(21) Appl. No.: 12/289,739

(22) Filed: Nov. 3, 2008

(30) Foreign Application Priority Data
Nov. 8, 2007 (JP) 2007-290339

(51) Int. Cl. C30B 19/08

(52) U.S. Cl. 117/77; 117/206

(57) ABSTRACT

The present invention provides an apparatus for producing a Group III nitride semiconductor, which enables production of a uniform Si-doped GaN crystal. In one embodiment of the invention, an apparatus for producing a Group III nitride semiconductor includes a supply tube for supplying nitrogen and silane, a Ga-supplying apparatus for supplying Ga melt to a crucible, and an Na-supplying apparatus for supplying Na melt to the crucible. Nitrogen and a dopant is mixed together, and the gas mixture is supplied through one single supply tube without provision of a conventionally employed supply tube for only supplying a dopant. Thus, dead space in a reaction vessel is reduced, and vaporization of Na is suppressed, whereby a high-quality, Si-doped GaN crystal can be produced.

### BACKGROUND OF THE INVENTION

1. Field of the Invention

The present invention relates to a method for producing a Group III nitride semiconductor crystal by the flux method employing alkali metal, and to an apparatus for producing the semiconductor crystal.

2. Background Art

The Na flux method is a typically known method for growing a Group III nitride semiconductor crystal. In this method, Na (sodium) and Ga (gallium) are melted and maintained at about 800° C., and gallium is reacted with nitrogen at a pressure of some ten atmospheres, whereby GaN (gallium nitride) is grown on a seed crystal.

Japanese Patent Application Laid-Open (kokai) No. 2004-292286 discloses an apparatus for producing a Group III nitride semiconductor crystal by the Na flux method, which apparatus has separately provided supply tubes for nitrogen, Ga, Na, and a dopant, respectively. The production apparatus realizes supply of nitrogen, Ga, Na, and a dopant at desired rates, to thereby perform crystal growth while maintaining compositional proportions of the components. As a result, a Group III nitride semiconductor with high compositional uniformity can be produced.

However, since the apparatus disclosed in the patent document is provided with a tube exclusively for supplying a dopant, the apparatus has a large number of supply tubes, which has caused an increase in dead space. Therefore, vaporization of Na is promoted, and Na vapor is liquefied or solidified in tubes, thereby clogging the tubes and inhibiting material feeding.

### SUMMARY OF THE INVENTION

In view of the foregoing, an object of the present invention is to provide a method for producing a high-quality doped Group III nitride semiconductor crystal, with vaporization of Na being suppressed. Another object of the invention is to provide an apparatus for producing such a semiconductor crystal.

Accordingly, in a first aspect of the present invention, there is provided an apparatus for producing a Group III nitride semiconductor, comprising a reaction vessel, a heating apparatus, and a crucible placed in the reaction vessel, the apparatus being provided for growing a Group III nitride semiconductor crystal through reaction, in the reaction vessel, of a molten mixture containing at least a Group III metal and an alkali metal and maintained in the crucible with a gas containing at least nitrogen, wherein the apparatus is provided with a first supply tube for supplying to the reaction vessel a mixture of a gaseous dopant and a gas containing at least nitrogen.

In a second aspect of the present invention, there is provided an apparatus for producing a Group III nitride semiconductor, comprising a reaction vessel, a heating apparatus, and a crucible placed in the reaction vessel, the apparatus being provided for growing a Group III nitride semiconductor crystal through reaction, in the reaction vessel, of a molten mixture containing at least a Group III metal and an alkali metal and maintained in the crucible with a gas containing at least nitrogen, wherein the apparatus is provided with a first supply tube for supplying a gas containing at least nitrogen to the reaction vessel and a second supply tube for supplying to the reaction vessel a molten Group III metal in which a dopant soluble in the Group III metal has been melted.

In a third aspect of the present invention, there is provided an apparatus for producing a Group III nitride semiconductor, comprising a reaction vessel, a heating apparatus, and a crucible placed in the reaction vessel, the apparatus being provided for growing a Group III nitride semiconductor crystal through reaction, in the reaction vessel, of a molten mixture containing at least a Group III metal and an alkali metal and maintained in the crucible with a gas containing at least nitrogen, wherein the apparatus is provided with a first supply tube for supplying a gas containing at least nitrogen to the reaction vessel and a third supply tube for supplying to the reaction vessel a molten alkali metal in which a dopant soluble in the alkali metal has been melted.

Although Na is generally employed as an alkali metal in the present invention, K (potassium) may also be employed. Alternatively, a Group 2 metal such as Mg (magnesium) or Ca (calcium), or Li (lithium) may be blended with the alkali metal. The term “a gas containing nitrogen” refers to a single-component gas or a gas mixture containing molecular nitrogen or a nitrogen compound, and the gas or gas mixture may further contain an inert gas such as a rare gas.

The dopant employed in the present invention includes the following dopant elements and a compound containing such a dopant element. Specifically, the n-type dopant element is C (carbon), Si (silicon), Ge (germanium), Sn (tin), or Pb (lead) (group 14 element), or O (oxygen), S (sulfur), Se (selenium), or Te (tellurium) (group 16 element). The p-type dopant element is Be (beryllium), Mg (magnesium), Ca (calcium), Sr (strontium), or Ba (barium) (group 2 element), or Zn (zinc) or Cd (cadmium) (group 12 element).

The gaseous dopant is, for example, a gas containing Si or O as a component element. Examples of the gaseous dopant include SiH₄ (silane), H₂O (water), and O₂ (oxygen). A dopant which is soluble in either a Group III metal or an alkali metal may be melted in either a Group III metal or an alkali metal.

The apparatus for producing a Group III nitride semiconductor according to the first aspect may further have a second supply tube for supplying a molten Group III metal or a third supply tube for supplying a molten alkali metal. The apparatus for producing a Group III nitride semiconductor according to the second aspect may further have a third supply tube for supplying a molten alkali metal. The apparatus for producing a Group III nitride semiconductor according to the third aspect may further have a second supply tube for supplying a molten Group III metal.

A fourth aspect of the invention is drawn to a specific embodiment of the apparatus for producing a Group III nitride semiconductor according to the first aspect, wherein the gaseous dopant is formed of a gas containing Si or O as a component element.

A fifth aspect of the invention is drawn to a specific embodiment of the apparatus for producing a Group III nitride semiconductor according to the second aspect, wherein the dopant soluble in the Group III metal is a group 2 element, a group 12 element, or a group 14 element, in the form of a single element.

A sixth aspect of the invention is drawn to a specific embodiment of the apparatus for producing a Group III nitride semiconductor according to the third aspect, wherein the dopant soluble in the alkali metal is an oxide.

Examples of the oxide forming the alkali metal-soluble dopant include SiO₂ (silicon dioxide), Ga₂O₃ (gallium oxide), Al₂O₃ (aluminum oxide), and In₂O₃ (indium oxide).

A seventh aspect of the invention is drawn to a specific embodiment of the apparatus for producing a Group III nitride semiconductor according to any of the first to sixth aspects, wherein the apparatus has a third supply tube for supplying an alkali metal to the reaction vessel, and the third supply tube is provided for supplying the alkali metal in mist form.

In an eighth aspect of the present invention, there is provided a method for producing a Group III nitride semiconductor crystal, comprising growing a Group III nitride semiconductor crystal through reaction of a molten mixture containing at least a Group III metal and an alkali metal with a gas containing at least nitrogen, wherein the method includes supplying a gas containing at least nitrogen and a dopant to the molten mixture during crystal growth, and the dopant is gaseous and supplied as a mixture with the gas containing at least nitrogen.

In a ninth aspect of the present invention, there is provided a method for producing a Group III nitride semiconductor crystal, comprising growing a Group III nitride semiconductor crystal through reaction of a molten mixture containing at least a Group III metal and an alkali metal with a gas containing at least nitrogen, wherein the method includes supplying a molten Group III metal, a gas containing at least nitrogen, and a dopant to the molten mixture during crystal growth, and the dopant is soluble in the molten Group III metal and supplied as a molten mixture with the molten Group III metal.

In a tenth aspect of the present invention, there is provided a method for producing a Group III nitride semiconductor crystal, comprising growing a Group III nitride semiconductor crystal through reaction of a molten mixture containing at least a Group III metal and an alkali metal with a gas containing at least nitrogen, wherein the method includes supplying a molten alkali metal, a gas containing at least nitrogen, and a dopant to the molten mixture during crystal growth, and the dopant is soluble in the molten alkali metal and supplied as a molten mixture with the molten alkali metal.

An eleventh aspect of the invention is drawn to a specific embodiment of the method for producing a Group III nitride semiconductor crystal according to the eighth aspect, wherein the gaseous dopant contains Si or O as a component element.

A twelfth aspect of the invention is drawn to a specific embodiment of the method for producing a Group III nitride semiconductor crystal according to the ninth aspect, wherein the dopant soluble in the Group III metal is a group 2 element, a group 12 element, or a group 14 element, in the form of a single element.

A thirteenth aspect of the invention is drawn to a specific embodiment of the method for producing a Group III nitride semiconductor crystal according to the tenth aspect, wherein the dopant soluble in the alkali metal is an oxide.

A fourteenth aspect of the invention is drawn to a specific embodiment of the method for producing a Group III nitride semiconductor crystal according to any of the eighth to thirteenth aspects, wherein the method includes supplying a molten alkali metal to the molten mixture during crystal growth, and the molten alkali metal is supplied in mist form.

According to the present invention, a dopant is supplied to a reaction vessel with at least a gas containing at least nitrogen, a molten Group III metal, or a molten alkali metal. Therefore, a supply tube exclusively for supplying a dopant is not needed, and the number of supply tubes does not increase. Thus, an increase in dead space and vaporization of alkali metal are prevented, whereby the compositional proportion of the molten mixture can be maintained at constant values, and a high-quality doped Group III nitride semiconductor crystal can be produced.

According to the seventh and fourteenth aspects of the invention, alkali metal is supplied in mist form, which promotes vaporization of the alkali metal. Thus, the vapor pressure of alkali metal present in the reaction vessel can be maintained virtually in an equilibrium state, whereby vaporization of alkali metal can be suppressed.

### BRIEF DESCRIPTION OF THE DRAWINGS

Various other objects, features, and many of the attendant advantages of the present invention will be readily appreciated as the same becomes better understood with reference to the following detailed description of the preferred embodiments when considered in connection with the accompanying drawings, in which:

FIG. 1 is a schematic view of the configuration of an apparatus for producing a Group III nitride semiconductor according to Embodiment 1;

FIG. 2 is a schematic view of the configuration of an apparatus for producing a Group III nitride semiconductor according to Embodiment 2;

FIG. 3 is a schematic view of the configuration of an apparatus for producing a Group III nitride semiconductor according to Embodiment 3; and

FIG. 4 is a schematic view of the configuration of an apparatus for producing a Group III nitride semiconductor according to Embodiment 4.

### DETAILED DESCRIPTION OF PREFERRED EMBODIMENTS

### Embodiment 1

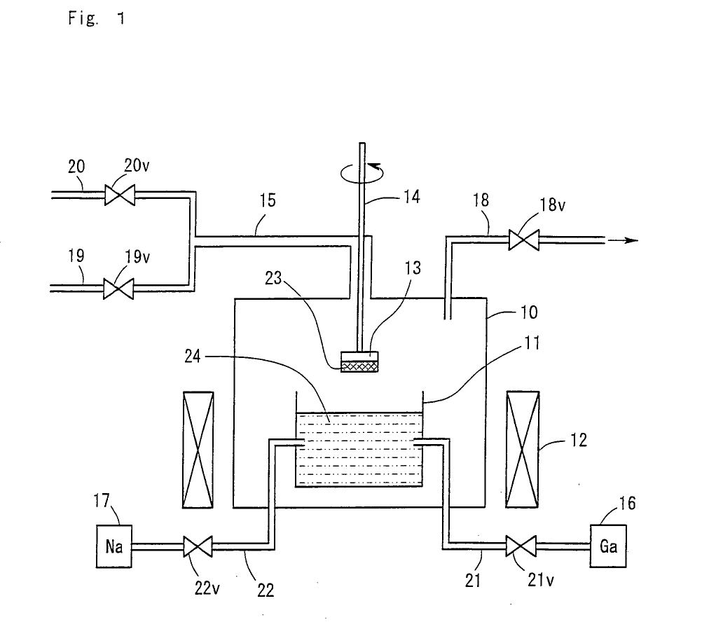

FIG. 1 is a schematic view of the configuration of an apparatus for producing a Group III nitride semiconductor according to Embodiment 1. As shown in FIG. 1, the apparatus for producing a Group III nitride semiconductor according to Embodiment 1 includes a reaction vessel 10; a crucible 11 which is placed in the reaction vessel 10 and which holds a Ga—Na melt 24; a heating apparatus 12 for heating the reaction vessel 10; a supporting member 13 for holding a seed crystal 23; a rotatable shaft 14 for rotating and moving the seed crystal 23 held by the supporting member 13; a supply tube 15 (corresponding to the first supply tube of the present invention) which is connected and opened to the reaction vessel 10, the tube being provided for supplying nitrogen and a dopant gas to the reaction vessel 10 through a gap between the rotatable shaft 14 and the reaction chamber 10; a Ga-supplying apparatus 16 for supplying Ga melt to the crucible 11; an Na-supplying apparatus 17 for supplying Na melt to the crucible 11; and a discharge pipe 18 for discharging the atmosphere gas in the reaction vessel 10 to the outside.

The reaction vessel 10 is a cylinder made of stainless steel and has resistance to pressure and heat. The crucible 11 is placed in the reaction vessel 10.

The crucible 11 placed in the reaction vessel 10 is made of BN (boron nitride). The crucible 11 holds a Ga—Na melt 24. To the crucible 11, a supply tube 21 (corresponding to the second supply tube of the present invention) and a supply tube 22 (corresponding to the third supply tube of the present invention) are connected. To the molten mixture 24 held in the crucible 11, Ga melt is supplied from the Ga-supplying apparatus 16 via the supply tube 21, and Na melt is supplied from the Na-supplying apparatus 17 via the supply tube 22.

The heating apparatus 12 is disposed outside the reaction vessel 10 so as to surround the vessel. The heating apparatus 12 regulates the inside temperature of the reaction vessel 10.

The supporting member 13 holds the seed crystal 23, and the rotatable shaft 14 connected to the supporting member 13 rotates and moves the seed crystal 23 up and down in a vertical direction. The rotatable shaft 14 vertically penetrates the reaction vessel 10. A gap exists between the rotatable shaft 14 and the reaction chamber 10.

The supply tube 15, which is connected and opened to the reaction vessel 10, supplies nitrogen and a dopant gas to the reaction vessel 10 through a gap between the rotatable shaft 14 and the reaction chamber 10. The supply tube 15 is branched on the upstream side thereof to provide a supply tube 19 for supplying a mixture of nitrogen and a dopant gas and a supply tube 20 for supplying nitrogen. The dopant gas is formed of a compound containing a dopant element as a component. Nitrogen supplied through the supply tube 20 and a mixture of nitrogen and a dopant supplied through the supply tube 19 are intermingled in the supply tube 15, and the gas mixture is fed to the reaction vessel 10. The supply tubes 19, 20 are provided with valves 19v, 20v, respectively, which valves control the flow rates of nitrogen and the dopant gas.

The dopant gas is, for example, silane, water, or oxygen. Silane is a compound having an n-dopant element (Si), and water is a compound having an n-dopant element (O).

The Ga-supplying apparatus 16 supplies Ga melt to the molten mixture 24 in the crucible 11 via the supply tube 21, and the Na-supplying apparatus 17 supplies Na melt to the molten mixture 24 in the crucible 11 via the supply tube 22. The supply tubes 21, 22 are provided with valves 21v, 22v, respectively, which valves control the flow rates of Ga and Na.

Next will be described the procedure of producing an Si-doped GaN crystal by means of the apparatus for producing a Group III nitride semiconductor of Embodiment 1.

Firstly, the rotatable shaft 14 is lifted up and maintained in the vertical direction, and the seed crystal 23 is fixed on the supporting member 13. Then, the reaction vessel 10 is closed, and the rotatable shaft 14 is vertically moved down to a position where the seed crystal 23 is placed in the crucible 11. The reaction vessel 10 is evacuated through the discharge pipe 18.

Subsequently, Ga melt and Na melt are fed to the crucible 11 by means of the Ga-supplying apparatus 16 and Na-supplying apparatus 17, whereby the molten mixture 24 having a constant Ga/Na ratio is maintained in the crucible 11. Then, a gas mixture of nitrogen and silane (dopant) is supplied to the reaction vessel 10 through the supply tube 15. The supply rate and discharge rate are regulated such that the internal pressure of the reaction vessel 10 is adjusted to 50 atm.

Then, the inside of the reaction vessel 10 is heated by means of the heating apparatus 12, and an Si-doped GaN crystal is grown on a surface of the seed crystal 23, while the inside of the reaction vessel 10 is maintained at 50 atm and 800° C. The seed crystal 23 is rotated through rotation of the rotatable shaft 14 so as to realize uniform crystal growth. During the crystal growth, nitrogen and silane are continuously supplied to the reaction vessel 10 through the supply tube 15, and Ga melt and Na melt are supplied to the molten mixture 24 by means of the Ga-supplying apparatus 16 and the Na-supplying apparatus 17 at appropriate timings to compensate consumption of Ga and vaporization of Na, whereby the molten mixture 24 has a constant Ga/Na ratio.

During crystal growth, evaporated Na diffuses inside the reaction vessel 10. However, according to the apparatus for producing a Group III nitride semiconductor of Embodiment 1 not having a supply tube for exclusively supplying silane, nitrogen and silane are supplied together. By virtue of the absence of a silane supply tube, the space which Na vapor can enter is reduced as compared with the case of a conventional semiconductor production apparatus, whereby vaporization of Na is suppressed. As a result, the Ga/Na ratio of the molten mixture 24 can be maintained constant, to thereby enhance uniformity of the grown crystal.

Thereafter, the temperature of the reaction vessel 10 is lowered to ambient temperature, to thereby complete production of an Si-doped GaN crystal.

As described above, according to the apparatus for producing a Group III nitride semiconductor of Embodiment 1, vaporization of Na is suppressed to thereby reliably attain constant compositional proportions of the molten mixture. Therefore, a high-quality, doped Group III nitride semiconductor can be produced.

Notably, in the apparatus for producing a Group III nitride semiconductor of Embodiment 1, the Ga-supplying apparatus 16, the Na-supplying apparatus 17, the supply tube 21 for supplying Ga melt, and the supply tube 22 for supplying Na melt are not essential. Alternatively, Ga and Na are placed in the crucible 11 in advance, and a Group III nitride semiconductor is produced without supplying Ga melt or Na melt during crystal growth. However, provision of the Ga-supplying apparatus 16, the Na-supplying apparatus 17, and the supply tubes 21, 22 so as to supply Ga melt and Na melt during crystal growth is preferred, since the Ga/Na ratio of the molten mixture 24 in the crucible 11 can be more reliably maintained.

### Embodiment 2

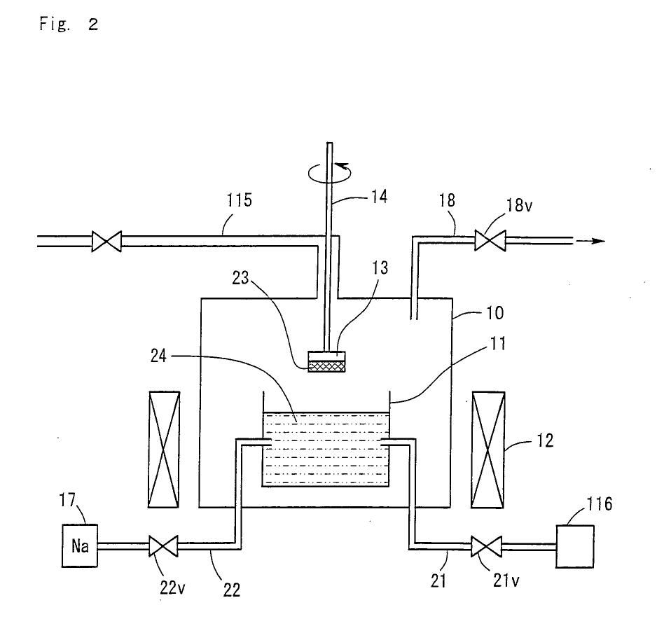

FIG. 2 is a schematic view of the configuration of an apparatus for producing a Group III nitride semiconductor according to Embodiment 2. The apparatus for producing a Group III nitride semiconductor according to Embodiment 2 has the same configuration as that of the apparatus of Embodiment 1, except that a supply tube 115 having no branching is employed instead of the supply tube 15 connected to branched supply tubes 19, 20, and that a Ga-supplying apparatus 116 for supplying Ga melt in which a dopant has been melted is employed instead of the Ga-supplying apparatus 16 for supplying Ga melt. In Embodiment 1, a gas mixture of nitrogen and silane is supplied to the reaction vessel 10 through the supply tube 15, but, in Embodiment 2, only nitrogen is supplied through the supply tube 115. The dopant which can be molten in Ga melt is, for example, an element of group 2, 12, or 14. Elements of groups 2 and 12 serve a p-type dopant, and elements of group 14 serve as an n-type dopant.

The procedure of producing a doped Group III nitride crystal by means of the apparatus for producing a Group III nitride semiconductor of Embodiment 2 is the same as employed in Embodiment 1. For example, through the procedure of Embodiment 1, an Si-doped GaN crystal can be produced by supplying Ga melt in which Si has been melted by means of the Ga-supplying apparatus 116.

According to the apparatus for producing a Group III nitride semiconductor of Embodiment 2, vaporization of Na is more suppressed, as compared to a conventional production apparatus, by virtue of the absence of a supply tube for supplying a dopant. Therefore, a high-quality, doped Group III nitride semiconductor can be produced.

Notably, in the apparatus for producing a Group III nitride semiconductor of Embodiment 2, the Na-supplying apparatus 17 and the supply tube 22 for supplying Na melt are not essential, and a Group III nitride semiconductor crystal may be produced without supplying Na during crystal growth. However, provision of the Na-supplying apparatus 17 and the supply tube 22 so as to supply Na melt during crystal growth is preferred, since the Ga/Na ratio of the molten mixture 24 in the crucible 11 can be more reliably maintained.

### Embodiment 3

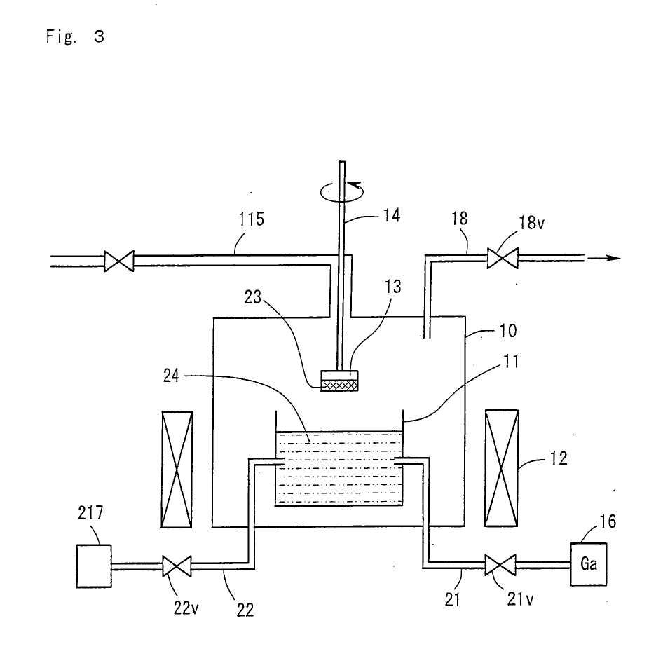

FIG. 3 is a schematic view of the configuration of an apparatus for producing a Group III nitride semiconductor according to Embodiment 3. The apparatus for producing a Group III nitride semiconductor according to Embodiment 3 has the same configuration as that of the apparatus of Embodiment 1, except that a supply tube 115 having no branching is employed instead of the supply tube 15 connected to branched supply tubes 19, 20, and that a Na-supplying apparatus 217 for supplying Na melt in which a dopant has been melted is employed instead of the Na-supplying apparatus 17 for supplying Na melt. The dopant which can be molten in Na melt is, for example, an oxide such as SiO₂, Ga₂O₃, Al₂O₃, and In₂O₃.

The procedure of producing a doped Group III nitride crystal by means of the apparatus for producing a Group III nitride semiconductor of Embodiment 3 is the same as employed in Embodiment 1. For example, through the procedure of Embodiment 1, an Si- and O-doped GaN crystal can be produced by supplying Na melt in which SiO₂ has been melted by means of the Na-supplying apparatus 217. Similarly, when Na melt in which Al₂O₃ or In₂O₃ has been melted is supplied by means of the Na-supplying apparatus 217, an O-doped AlGaN crystal or an O-doped InGaN crystal can be produced.

According to the apparatus for producing a Group III nitride semiconductor of Embodiment 3, vaporization of Na is more suppressed, as compared to a conventional production apparatus, by virtue of the absence of a supply tube for supplying a dopant. Therefore, a high-quality, doped Group III nitride semiconductor can be produced.

Notably, in the apparatus for producing a Group III nitride semiconductor of Embodiment 3, the Ga-supplying apparatus 16 and the supply tube 21 for supplying Ga melt are not essential, and a Group III nitride semiconductor crystal may be produced without supplying Ga during crystal growth. However, provision of the Ga-supplying apparatus 16 and the supply tube 21 so as to supply Ga melt during crystal growth is preferred, since the Ga/Na ratio of the molten mixture 24 in the crucible 11 can be more reliably maintained.

### Embodiment 4

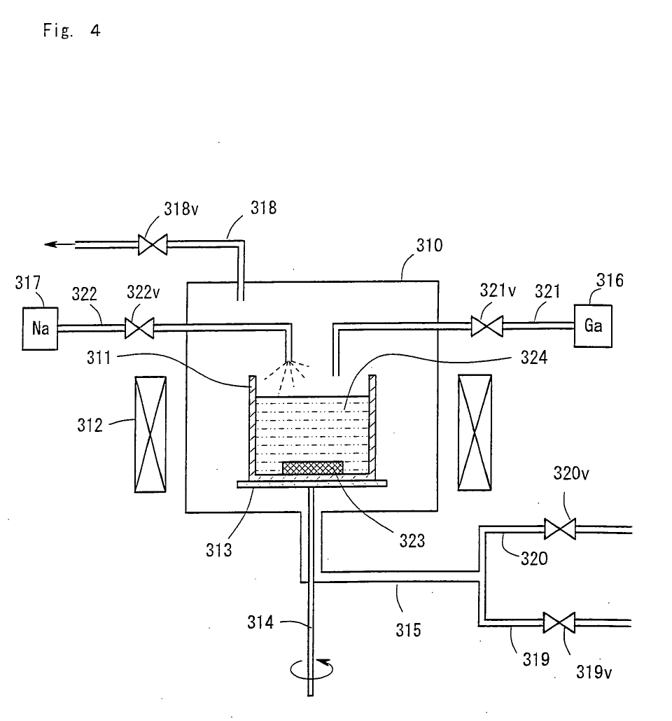

FIG. 4 is a schematic view of the configuration of an apparatus for producing a Group III nitride semiconductor according to Embodiment 4. The apparatus for producing a Group III nitride semiconductor according to Embodiment 4 includes a reaction vessel 310; a crucible 311 which is placed in the reaction vessel 310 and which holds a Ga—Na melt 324 and a seed crystal 323; a heating apparatus 312 for heating the reaction vessel 310; a supporting member 313 for supporting the crucible 311; a rotatable shaft 314 which is connected to the supporting member 313 and which is provided for rotating and moving the crucible 311; a supply tube 315 which is provided for supplying nitrogen and a dopant gas to the reaction vessel 310 through a gap between the rotatable shaft 314 and the reaction chamber 310; a Ga-supplying apparatus 316 for supplying Ga melt to the crucible 311; an Na-supplying apparatus 317 for supplying Na melt to the crucible 311; and a discharge pipe 318 for discharging the atmosphere gas in the reaction vessel 310 to the outside.

The supporting member 313 holds the crucible 311, and the rotatable shaft 314 connected to the supporting member 313 rotates and moves the crucible 311 up and down in a vertical direction. The rotatable shaft 314 vertically penetrates the reaction vessel 310. A gap exists between the rotatable shaft 314 and the reaction chamber 310.

The supply tube 315 is branched on the upstream side thereof to provide a supply tube 319 for supplying a mixture of nitrogen and a dopant gas and a supply tube 320 for supplying nitrogen. The supply tubes 319, 320 are provided with valves 319v, 320v, respectively, which valves control the flow rates of nitrogen and the dopant gas.

The Ga-supplying apparatus 316 supplies Ga melt to the molten mixture 324 held in the crucible 311 via the supply tube 321. The supply tube 321 is provided with a valve 321v which controls the flow rates of Ga melt.

The Na-supplying apparatus 317 supplies Na melt in mist form to the reaction vessel 310 via the supply tube 322. The supply tube 322 is provided with a valve 322v which controls the flow rates of Na melt.

Next will be described the procedure of producing an Si-doped GaN crystal by means of the apparatus for producing a Group III nitride semiconductor of Embodiment 4.

Firstly, the rotatable shaft 314 is lifted up and maintained in the vertical direction, and the seed crystal 323, Ga, and Na are placed in the crucible 311. The crucible 311 is placed on the supporting member 313. Then, the rotatable shaft 314 is vertically moved down so as to transfer the crucible 311 into the reaction vessel 310, and the reaction vessel 310 is closed.

Through opening the valve 318v disposed in the discharge pipe 318, the reaction vessel 310 is evacuated. Then, a gas mixture of nitrogen and silane (dopant) is supplied to the reaction vessel 310 through the supply tube 315. The supply rate and discharge rate are regulated such that the internal pressure of the reaction vessel 310 is adjusted to 50 atm.

Then, the inside of the reaction vessel 310 is heated by means of the heating apparatus 312, and an Si-doped GaN crystal is grown on a surface of the seed crystal 323, while the inside of the reaction vessel 310 is maintained at 50 atm and 800° C. The crucible 311 is rotated through rotation of the rotatable shaft 314 so as to stir the molten mixture 324 for realizing uniform crystal growth. During the crystal growth, nitrogen and silane are continuously supplied to the reaction vessel 310 through the supply tube 315, and Ga melt and Na melt are supplied to the molten mixture 324 by means of the Ga-supplying apparatus 316 and the Na-supplying apparatus 317 at appropriate timings to compensate consumption of Ga and vaporization of Na, whereby the molten mixture 324 has a constant Ga/Na ratio.

Similar to other Embodiments, during crystal growth, vaporization of Na is more suppressed as compared with a conventional semiconductor production apparatus, by virtue of the absence of a silane supply tube. On the other hand, since Na melt is supplied in mist form, vaporization of Na is promoted, and the vapor pressure of Na can be maintained substantially in an equilibrium state. As a result, vaporization of Na from the molten mixture 324 can be more suppressed.

Thereafter, the temperature of the reaction vessel 310 is lowered to ambient temperature, to thereby complete production of an Si-doped GaN crystal.

As described above, according to the apparatus for producing a Group III nitride semiconductor of Embodiment 4, vaporization of Na is suppressed through supply of Na in mist form. Therefore, a high-quality, doped Group III nitride semiconductor can be produced.

In the Embodiments, Na is employed as a flux. However, other alkali metals such as Li and K, alkaline earth metals such as Mg and Ca, and mixtures thereof may also be used. Also, instead of nitrogen, a compound containing nitrogen such as ammonia or a mixture of nitrogen and an inert gas such as argon may also be supplied to the reaction vessel.

In the Embodiments, a dopant is supplied in the form of a mixture with any one of the nitrogen, Ga melt, and Na melt. However, the dopant may be supplied as mixtures with two or more species of the above media. For example, a mixture of nitrogen and silane, and Ga melt in which Mg has been melted may be employed for supplying Si (n-type dopant) and Mg (p-type dopant).

In Embodiments 1 and 4, nitrogen and a gas mixture of nitrogen and dopant gas are intermingled before supplying to the reaction vessel. However, alternatively, a gas mixture of nitrogen and dopant gas may be directly supplied to the reaction vessel, or a dopant gas and nitrogen may be mixed together before supplying to the reaction vessel.

### INDUSTRIAL APPLICABILITY

The present invention is useful for production of a Group III nitride semiconductor crystal.

What is claimed is:

1. An apparatus for producing a Group III nitride semiconductor, comprising a reaction vessel, a heating apparatus, and a crucible placed in the reaction vessel, the apparatus being provided for growing a Group III nitride semiconductor crystal through reaction, in the reaction vessel, of a molten mixture containing at least a Group III metal and an alkali metal and maintained in the crucible with a gas containing at least nitrogen,
wherein the apparatus is provided with a first supply tube for supplying to the reaction vessel a mixture of a gaseous dopant and a gas containing at least nitrogen.

2. An apparatus for producing a Group III nitride semiconductor, comprising a reaction vessel, a heating apparatus, and a crucible placed in the reaction vessel, the apparatus being provided for growing a Group III nitride semiconductor crystal through reaction, in the reaction vessel, of a molten mixture containing at least a Group III metal and an alkali metal and maintained in the crucible with a gas containing at least nitrogen,
wherein the apparatus is provided with a first supply tube for supplying a gas containing at least nitrogen to the reaction vessel and a second supply tube for supplying to the reaction vessel a molten Group III metal in which a dopant soluble in the Group III metal has been melted.

3. An apparatus for producing a Group III nitride semiconductor, comprising a reaction vessel, a heating apparatus, and a crucible placed in the reaction vessel, the apparatus being provided for growing a Group III nitride semiconductor crystal through reaction, in the reaction vessel, of a molten mixture containing at least a Group III metal and an alkali metal and maintained in the crucible with a gas containing at least nitrogen,
wherein the apparatus is provided with a first supply tube for supplying a gas containing at least nitrogen to the reaction vessel and a third supply tube for supplying to the reaction vessel a molten alkali metal in which a dopant soluble in the alkali metal has been melted.

4. An apparatus for producing a Group III nitride semiconductor according to claim 1, wherein the gaseous dopant is formed of a gas containing Si or O as a component element.

5. An apparatus for producing a Group III nitride semiconductor according to claim 2, wherein the dopant soluble in the Group III metal is a group 2 element, a group 12 element, or a group 14 element, in the form of a single element.

6. An apparatus for producing a Group III nitride semiconductor according to claim 3, wherein the dopant soluble in the alkali metal is an oxide.

7. An apparatus for producing a Group III nitride semiconductor according to claim 1,
wherein the apparatus has a third supply tube for supplying an alkali metal to the reaction vessel, and
the third supply tube is provided for supplying the alkali metal in mist form.

8. An apparatus for producing a Group III nitride semiconductor according to claim 2,
wherein the apparatus has a third supply tube for supplying an alkali metal to the reaction vessel, and
the third supply tube is provided for supplying the alkali metal in mist form.

9. An apparatus for producing a Group III nitride semiconductor according to claim 3,
wherein the apparatus has a third supply tube for supplying an alkali metal to the reaction vessel, and
the third supply tube is provided for supplying the alkali metal in mist form.

10. A method for producing a Group III nitride semiconductor crystal, comprising growing a Group III nitride semiconductor crystal through reaction of a molten mixture containing at least a Group III metal and an alkali metal with a gas containing at least nitrogen,
wherein the method includes supplying a gas containing at least nitrogen and a dopant to the molten mixture during crystal growth, and
the dopant is gaseous and supplied as a mixture with the gas containing at least nitrogen.

11. A method for producing a Group III nitride semiconductor crystal, comprising growing a Group III nitride semiconductor crystal through reaction of a molten mixture containing at least a Group III metal and an alkali metal with a gas containing at least nitrogen,
wherein the method includes supplying a molten Group III metal, a gas containing at least nitrogen, and a dopant to the molten mixture during crystal growth, and
the dopant is soluble in the molten Group III metal and supplied as a molten mixture with the molten Group III metal.

12. A method for producing a Group III nitride semiconductor crystal, comprising growing a Group III nitride semiconductor crystal through reaction of a molten mixture containing at least a Group III metal and an alkali metal with a gas containing at least nitrogen,
wherein the method includes supplying a molten alkali metal, a gas containing at least nitrogen, and a dopant to the molten mixture during crystal growth, and
the dopant is soluble in the molten alkali metal and supplied as a molten mixture with the molten alkali metal.

13. A method for producing a Group III nitride semiconductor crystal according to claim 10, wherein the gaseous dopant contains Si or O as a component element.

14. A method for producing a Group III nitride semiconductor crystal according to claim 11, wherein the dopant soluble in the Group III metal is a group 2 element, a group 12 element, or a group 14 element, in the form of a single element.

15. A method for producing a Group III nitride semiconductor crystal according to claim 12, wherein the dopant soluble in the alkali metal is an oxide.

16. A method for producing a Group III nitride semiconductor crystal according to claim 10, wherein the method includes supplying a molten alkali metal to the molten mixture during crystal growth, and
the molten alkali metal is supplied in mist form.

17. A method for producing a Group III nitride semiconductor crystal according to claim 11, wherein the method includes supplying a molten alkali metal to the molten mixture during crystal growth, and
the molten alkali metal is supplied in mist form.

18. A method for producing a Group III nitride semiconductor crystal according to claim 12, wherein the method includes supplying a molten alkali metal to the molten mixture during crystal growth, and
the molten alkali metal is supplied in mist form.
